(19) United States
(12) Patent Application Publication
(10) Pub. No.: US 2024/0064949 A1
(43) Pub. Date: Feb. 22, 2024

(54) TRANSFER DEVICE

(71) Applicant: Innolux Corporation, Miaoli County (TW)

(72) Inventor: Jen-Hai Chi, Miaoli County (TW)

(73) Assignee: Innolux Corporation, Miaoli County (TW)

(21) Appl. No.: 18/356,192

(22) Filed: Jul. 20, 2023

Related U.S. Application Data
(60) Provisional application No. 63/398,232, filed on Aug. 16, 2022.

(30) Foreign Application Priority Data
Apr. 21, 2023 (CN) 202310435115.2

(51) Int. Cl. H05K 13/04

(52) U.S. Cl. CPC H05K 13/0411

(57) ABSTRACT

A transfer device, including a substrate and multiple pick-and-place modules, is provided. The pick-and-place modules are disposed on the substrate to transfer multiple electronic components onto the substrate. At least one pick-and-place module includes a rotating arm that rotates vertically relative to the substrate.

### CROSS-REFERENCE TO RELATED APPLICATION

This application claims the priority benefits of U.S. provisional application Ser. No. 63/398,232, filed on Aug. 16, 2022, and China application serial no. 202310435115.2, filed on Apr. 21, 2023. The entirety of each of the above-mentioned patent applications is hereby incorporated by reference herein and made a part of this specification.

### BACKGROUND

### Technical Field

The disclosure relates to a transfer device, and more particularly to a transfer device capable of transferring an electronic component.

### Description of Related Art

Currently, the rotating arm of the transfer device rotates horizontally relative to the substrate, so the size of the substrate is limited by the radius of the rotating arm. For example, when the rotation radius of the rotating arm is A, this A represents the limit of the construction distance. Moreover, the substrate is laid flat at 180 degrees, so the maximum allowable size of the substrate is 2A. That is, the current transfer device design is limited by the radius of the rotating arm, which cannot achieve large-scale operation of the substrate.

### SUMMARY

The disclosure relates to a transfer device that may improve the tact time regardless of the size of the substrate.

According to the embodiments of the disclosure, the transfer device includes a substrate and multiple pick-and-place modules. The pick-and-place modules are disposed on the substrate to transfer multiple electronic components onto the substrate. At least one pick-and-place module includes a rotating arm rotating vertically relative to the substrate.

Based on the above, in the embodiments of the disclosure, the rotating arm of the pick-and-place modules rotates vertically relative to the substrate. Thus, the transfer device of the disclosure is not limited by a radius of the rotating arm, and may be applied to large-size substrates. Furthermore, the rotating arm of the disclosure rotates vertically, which means that the radius of the rotating arm is reduced. Thus, the tact time may be effectively reduced, and large-scale electronic component transfer may be efficiently performed. In addition, since the transfer device of the disclosure includes multiple pick-and-place modules, the tact time may be reduced.

### BRIEF DESCRIPTION OF THE DRAWINGS

The accompanying drawings are included to provide a further understanding of the disclosure, and are incorporated in and constitute a part of this specification. The drawings illustrate embodiments of the disclosure, and together with the description serve to explain principles of the disclosure.

FIG. 1A is a schematic view of a transfer device of the disclosure.

FIG. 1B is a schematic view of a rotating arm in the pick-and-place modules of FIG. 1A.

FIG. 2 is a schematic view of another transfer device of the disclosure.

FIG. 3 is a schematic view of yet another transfer device of the disclosure.

FIG. 4 is a schematic view of yet another transfer device of the disclosure.

### DESCRIPTION OF THE EMBODIMENTS

The disclosure can be understood by referring to the following detailed description in conjunction with the accompanying drawings. It should be noted that, for the ease of understanding by the readers and for the brevity of the accompanying drawings, multiple drawings in the disclosure only depict a portion of the electronic device, and the specific elements in the drawings are not drawn according to the actual scale. In addition, the number and size of each of the elements in the figures are for illustration purposes only, and are not intended to limit the scope of the disclosure.

Certain terms may be used throughout the disclosure and the appended claims to refer to specific elements. It should be understood by those skilled in the art that electronic device manufacturers may refer to the same elements by different names. The disclosure does not intend to distinguish between elements that have the same function but have different names.

In the following description and claims, words such as “comprising” and “including” are open-ended words, so they should be interpreted as meaning “including but not limited to . . . ”.

In addition, relative terms, such as “below” or “bottom” and “above” or “top,” may be used in the embodiments to describe a relative relationship of one element of the drawings to another element. It will be understood that if a device in the figures is turned upside down, elements described on a “lower” side would become elements described on an “upper” side.

In some embodiments of the disclosure, terms related to joining and connecting, such as “connected”, “interconnected”, etc., unless otherwise defined, may mean that two structures are in direct contact, or may also mean that two structures are not in direct (indirect) contact, in which there are other structures located between these two structures. The terms related to joining and connecting can also include the case where both structures are movable, or both structures are fixed. In addition, the term “coupling” includes the transfer of energy between two structures through direct or indirect electrical connection, or the transfer of energy between two separate structures through mutual induction.

It should be understood that when an element or layer is referred to as being “on” or “connected to” another element or layer, it may be directly on or directly connected to this other element or layer, or there may be an intervening element or layer in between (indirect case). In contrast, when an element is referred to as being “directly on” or “directly connected to” another element or layer, there are no intervening elements or layers present.

In the disclosure, a length, width, thickness, height, area or distance or space between components may be measured by using an optical microscopy (OM), a scanning electron microscope (SEM), an α-step, an ellipsometer or other suitable methods. In detail, according to some embodiments, a scanning electron microscope may be used to obtain a cross-sectional structure image including the components to be measured, and measure a length, width, thickness, height or area of each component, or a distance or spacing between the components, but the disclosure is not limited thereto.

Furthermore, the terms “a given range is from a first value to a second value”, “a given range is within a range from the first value to the second value” means that the given range includes the first value, the second value, and other values in between. If a first direction is perpendicular to a second direction, an angle between the first direction and the second direction may be between 80 degrees and 100 degrees; if the first direction is parallel to the second direction, an angle between the first direction and the second direction may be between 0 degrees and 10 degrees. The terms “about”, “equal to”, “equal” or “same”, “substantially” or “generally” are interpreted as within 20% of a given value or range, or interpreted as within 10%, 5%, 3%, 2%, 1%, or 0.5% of the given value or range.

Although the terms “first”, “second”, “third”, . . . , may be used to describe various constituent elements, the constituent elements are not limited by the terms. The terms are only used to distinguish a single constituent element from other constituent elements in the specification. The same terms may not be used in the claim, but replaced by first, second, third . . . according to the order in which the elements are declared in the claim. Therefore, in the following description, the first constituent element may be the second constituent element in the claim.

Unless otherwise defined, all terms (including technical and scientific terms) used herein have the same meaning as commonly understood by one of ordinary skill in the art to which this disclosure belongs. It is understood that these terms, such as those defined in commonly used dictionaries, should be interpreted as having meanings consistent with the relevant art and the background or context of the disclosure, and should not be interpreted in an idealized or overly formal manner, unless otherwise defined herein.

It should be noted that, in the following embodiments, the technical features in several different embodiments can be replaced, reorganized, and mixed to complete other embodiments without departing from the spirit of the disclosure.

References of the exemplary embodiments of the disclosure are to be made in detail. Examples of the exemplary embodiments are illustrated in the drawings. If applicable, the same reference numerals in the drawings and the descriptions indicate the same or similar parts.

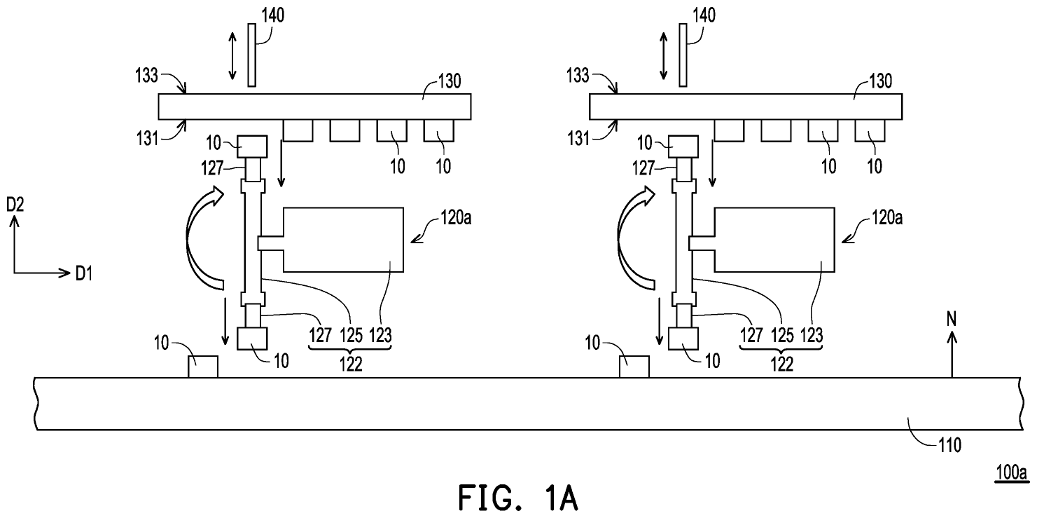

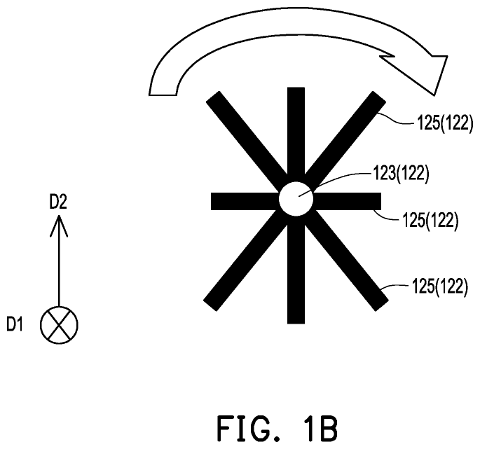

FIG. 1A is a schematic view of a transfer device of the disclosure. FIG. 1B is a schematic view of a rotating arm in the pick-and-place modules of FIG. 1A. First, referring to FIG. 1A, in this embodiment, a transfer device 100a includes a substrate 110 and multiple pick-and-place modules (two pick-and-place modules 120a are schematically shown). The pick-and-place modules 120a are disposed on the substrate 110 for transferring multiple electronic components 10 onto the substrate 110. At least one pick-and-place module 120a includes a rotating arm 122 that rotates vertically relative to the substrate 110. For example, the rotating arm 122 may rotate around a first direction D1. The first direction D1 is perpendicular to a normal direction N of the substrate 110. That is, the first direction D1 here is, for example, an X-axis direction or a Y-axis direction, but not limited thereto.

More specifically, referring to FIG. 1A and FIG. 1B together, this embodiment, the rotating arm 122 includes a rotating portion 123, multiple arm portions 125, and multiple pick up portions 127. The arm portions 125 are connected to the rotating portion 123, and the pick up portions 127 are disposed on the arm portions 125. The pick up portions 127 here are, for example, nozzles, but not limited thereto. Furthermore, the transfer device 100a of this embodiment further includes a release film 130. The electronic components 10 are disposed on a first side 131 of the release film 130. The electronic component 10 here may include a passive element, an active element, or a combination of the foregoing, such as a capacitor, a resistor, an inductor, a diode, a transistor, a sensor, a microelectromechanical system (MEMS) element, a chip, and the like. The diode may include light-emitting diodes, photodiodes, and varicap diodes, but is not limited thereto. In some embodiments, the electronic component 10 may be a modulation element, such as an element for modulating a frequency, a phase, and/or an amplitude of electromagnetic waves. In addition, the transfer device 100a of this embodiment further includes at least one pin (a pin 140 is schematically shown) located on a second side 133 of the release film 130 relative to the first side 131. In the disclosure, the release film 130 may be, for example, a blue film, but not limited thereto. In some embodiments, the pick-and-place modules 120a include the release film 130, the electronic components 10, and the pin 140. As shown in FIG. 1A, the substrate 110, the pick-and-place modules 120a, and the release film 130 are disposed along a second direction D2 parallel to the normal direction N. The pick-and-place modules 120a are located between the release film 130 and the substrate 110. The first direction D1 is perpendicular to the second direction D2. Operationally, the pick up portions 127 of the pick-and-place modules 120a pick up the electronic component 10 located on the first side 131 of the release film 130. At this time, the pin 140 touches the second side 133 of the release film 130, causing a deformation of the release film 130, so that the electronic components 10 on the first side 131 of the release film 130 may be taken off by the pick up portions 127 and transferred onto the substrate 10 through the vertical rotation of the rotating arm 122.

The rotating arm 122 of the pick-and-place modules 120a of the disclosure rotates around the first direction D1 of the normal direction N perpendicular to the substrate 110, that is, the rotating arm 122 rotates vertically relative to the substrate 110. Thus, the transfer device 100a of the disclosure does not need to consider the size of the substrate 110, that, is, the size of the substrate 110 is not limited by the radius of the rotating arm 122, so it may be applied to a large-sized substrate 110. Furthermore, since the rotating arm 122 of the disclosure rotates vertically, the radius of the rotating arm 122 may be reduced. In response to the radius of the rotating arm 122 being reduced, the rotation speed may be accelerated. Thus, the tact time may be effectively reduced and the accuracy of placing the component may be improved. Moreover, the large-scale electronic component 10 transfer may be efficiently performed to increase the production capacity and the yield of the electronic device. In addition, since the transfer device 100a of the disclosure includes multiple pick-and-place modules 120a, the tact time may be improved. In the disclosure, electronic devices produced through the transfer device may include display devices, antenna devices, sensing devices, light emitting devices, or tiled devices, but are not limited thereto. The electronic device may include a bendable or flexible electronic device. It should be noted that, the electronic device can be any arrangement and combination of the foregoing, but not limited thereto.

It is to be noted that the following embodiments use the reference numerals and a part of the contents of the above embodiments, and the same reference numerals are used to denote the same or similar elements, and the description of the same technical contents is omitted. For the description of the omitted part, reference may be made to the above embodiments, and details are not described in the following embodiments.

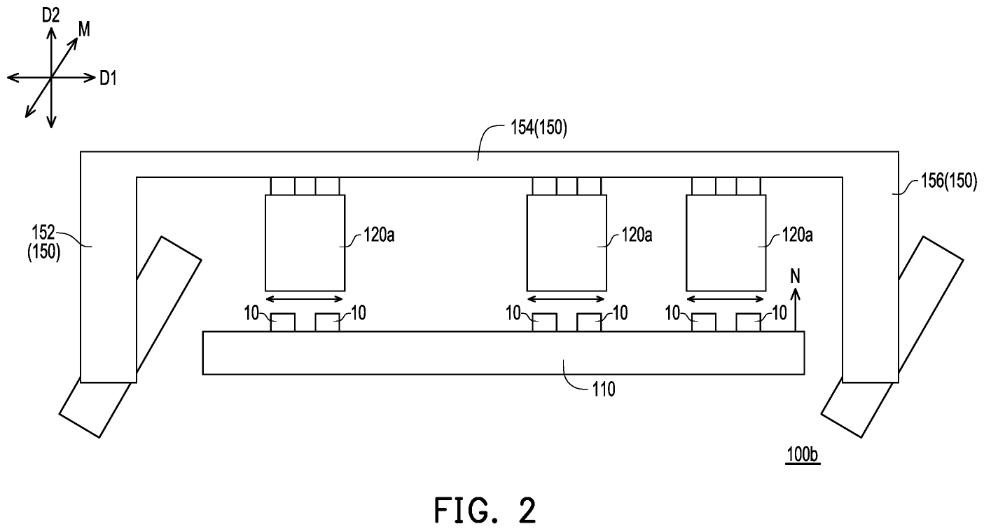

FIG. 2 is a schematic view of another transfer device of the disclosure. Referring to FIG. 1A and FIG. 2 together, a transfer device 100b of this embodiment is similar to the transfer device 100a of FIG. 1A, which will not be repeated herein. The difference between FIG. 1A and FIG. 2 is that, in this embodiment, the transfer device 100b further includes a gantry structure 150 disposed corresponding to the substrate 110, and the pick-and-place modules 120a are disposed on the gantry structure 150. More specifically, the gantry structure 150 includes a first portion 152, a second portion 154, and a third portion 156. The second portion 154 is disposed between the first portion 152 and the third portion 156, and the pick-and-place modules 120a are disposed on the second portion 154. The first portion 152 and the third portion 156 are disposed on two corresponding sides of the substrate 110, and the second portion 154 is perpendicular to the normal direction N. That is, the second portion 154 is parallel to the substrate 110, and the gantry structure 150 is inverted U-shaped. The pick-and-place modules 120a disposed on the second portion 154 moves in an extension direction (e.g., first direction D1) of the second portion 154, and the gantry structure 150 disposed corresponding to the substrate 110 moves in a moving direction M. The moving direction M is perpendicular to the normal direction N and/or the extending direction of the second portion 154. The extending direction (first direction D1) of the second portion 154 is, for example, the X-axis direction, and the moving direction M is, for example, the Y-axis direction. In some embodiments, the extension direction of the second portion 154 may be, for example, other directions perpendicular to the normal direction N of the substrate 110. The gantry structure 150 may move in the moving direction M controlled by, for example, a motor, but not limited to be controlled by a motor. The pick-and-place modules 120a may move in the extension direction of the second portion 154 controlled by, for example, a motor, but not limited thereto.

The pick-and-place modules 120a of the disclosure may move in the extension direction of the second portion 154 (e.g., first direction D1), and the gantry structure 150 may move in the moving direction M. Thus, the number of components (i.e., the electronic component 10) placed on the substrate 110 may be greatly increased, and the production capacity may be greatly increased, thereby achieving the purpose of mass production.

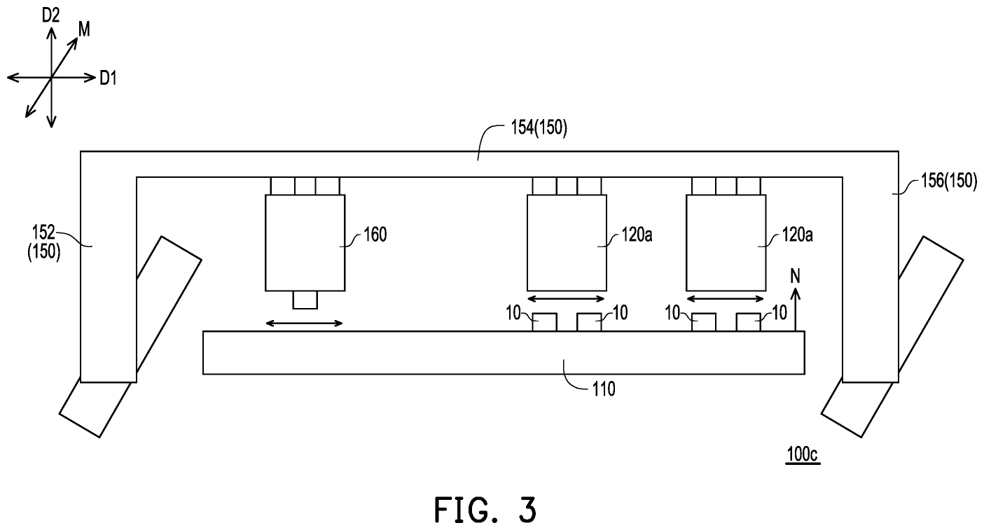

FIG. 3 is a schematic view of yet another transfer device of the disclosure. Referring to FIG. 2 and FIG. 3 together, a transfer device 100c of this embodiment is similar to the transfer device 100b of FIG. 2, and will not be repeated herein. The difference between FIG. 2 and FIG. 3 is that, in this embodiment, the transfer device 100c further includes a tin spraying module 160. The tin spraying module 160 is disposed on the second portion 154. In another embodiment, a flux module may also replace the tin spraying module 160. Alternatively, the tin spraying module 160 and the flux module may be disposed on the second portion 154 of the gantry structure 150 at the same time, all of which belong to the range to be protected by the disclosure. In short, the transfer device 100c of the disclosure is a combination of multiple function modules.

The transfer device 100c of the disclosure may further include at least one of the tin spraying module 160 and the flux module. Thus, it is possible to spray a solder paste (e.g., tin and/or flux) directly on the electronic components 10 transferred onto the substrate 110, which may effectively save the time between transferring and coating the solder paste, so as to avoid the problem of solder paste drying due to too long waiting time, and may improve production yield.

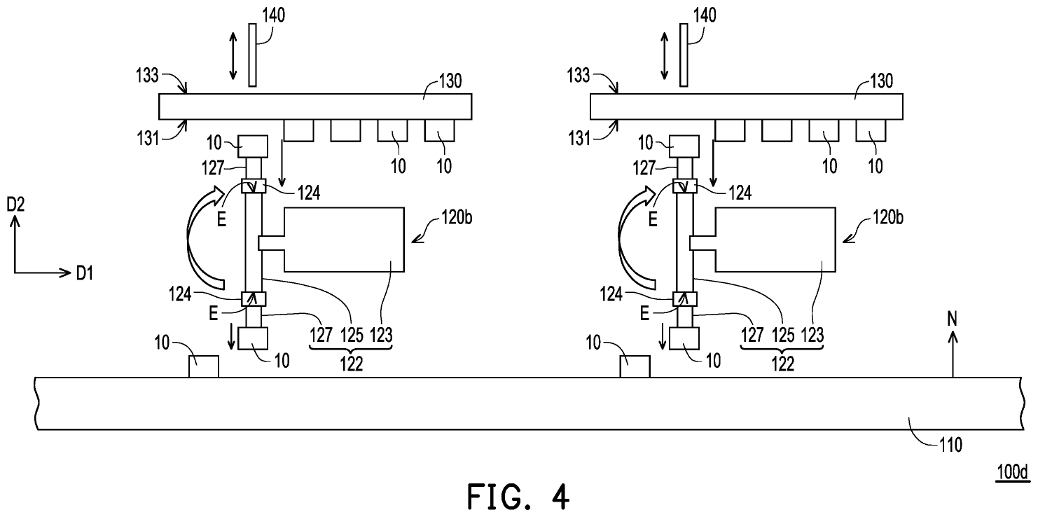

FIG. 4 is a schematic view of yet another transfer device of the disclosure. Referring to FIG. 1A and FIG. 4 together, a transfer device 100d of this embodiment is similar to the transfer device 100a of FIG. 1A, which will not be repeated herein. The difference between FIG. 1A and FIG. 4 is that, in this embodiment, the pick-and-place modules 120b of the transfer device 100d further includes a rotary motor 124, which is disposed at an end E of the arm portions 125 of the rotating arm 122, and the rotary motor rotates horizontally relative to the substrate 110. For example, the rotary motor 124 may rotate around the second direction D2. The second direction D2 is parallel to the normal direction N, that is, the second direction D2 here is, for example, a Z-axis direction, but not limited thereto.

The placement of the electronic component 10 does not necessarily present a same fixed angle, sometimes it may be a variety of different angles. Thus, the pick-up angle of the pick-up portion 127 may be adjusted through the rotary motor 124 located between the arm portions 125 and the pick-up portion 127, then the electronic components 10 with a suitable angle are placed on the substrate 110. In this way, it may be used to meet the special placement requirements for the electronic component 10 in electronic device.

To sum up, in the embodiments of the disclosure, the rotating arms of the pick-and-place modules rotate vertically relative to the substrate. Thus, the transfer device of the disclosure is not limited by a radius of the rotating arm, and may be applied to large-size substrates. Furthermore, the rotating arm of the disclosure rotates vertically, which means that the radius of the rotating arm is reduced. Thus, the tact time may be effectively reduced, and large-scale electronic component transfer may be efficiently performed. In addition, since the transfer device of the disclosure includes multiple pick-and-place modules, the tact time may be reduced.

Finally, it should be noted that the foregoing embodiments are only used to illustrate the technical solutions of the disclosure, but not to limit the disclosure; although the disclosure has been described in detail with reference to the foregoing embodiments, persons of ordinary skill in the art should understand that the technical solutions described in the foregoing embodiments can still be modified, or parts or all of the technical features thereof can be equivalently replaced; however, these modifications or substitutions do not deviate the essence of the corresponding technical solutions from the scope of the technical solutions of the embodiments of the disclosure.

What is claimed is:

1. A transfer device, comprising:
a substrate; and
a plurality of pick-and-place modules, disposed on the substrate to transfer a plurality of electronic components onto the substrate, wherein at least one of the pick-and-place modules comprises:
a rotating arm, rotating vertically relative to the substrate.

2. The transfer device according to claim 1, further comprising:
a gantry structure, disposed corresponding to the substrate, wherein the pick-and-place modules are disposed on the gantry structure.

3. The transfer device according to claim 2, wherein the gantry structure comprises a first portion, a second portion, and a third portion, the second portion is disposed between the first portion and the third portion, and the pick-and-place modules are disposed on the second portion.

4. The transfer device according to claim 3, wherein the pick-and-place modules disposed on the second portion move in a first direction, the gantry structure disposed corresponding to the substrate moves in a moving direction, wherein the moving direction is perpendicular to a normal direction of the substrate and the first direction.

5. The transfer device according to claim 4, wherein the gantry structure disposed corresponding to the substrate moves in the moving direction controlled by a motor.

6. The transfer device according to claim 4, wherein the pick-and-place modules disposed on the second portion move in the first direction controlled by a motor.

7. The transfer device according to claim 4, wherein the first direction is an X-axis direction, and the moving direction is a Y-axis direction.

8. The transfer device according to claim 3, wherein the first portion and the third portion are disposed on two corresponding sides of the substrate, and the second portion is parallel to the substrate.

9. The transfer device according to claim 8, wherein the gantry structure is inverted U-shaped.

10. The transfer device according to claim 3, further comprising:
at least one of a tin spraying module and a flux module, wherein at least one of the tin spraying module and the flux module is disposed on the second portion.

11. The transfer device according to claim 1, wherein the rotating arm comprises:
a rotating portion;
a plurality of arm portions, connected to the rotating portion; and
a plurality of pick up portions, disposed on the arm portions.

12. The transfer device according to claim 11, wherein the at least one of the pick-and-place modules further comprises:
a rotary motor, disposed at an end of the arm portions of the rotating arm and rotating horizontally relative to the substrate.

13. The transfer device according to claim 12, wherein each of the pick up portions comprises a nozzle.

14. The transfer device according to claim 1, wherein the transfer device or the at least one of the pick-and-place modules further comprises:
a release film, wherein the electronic components are disposed on a first side of the release film.

15. The transfer device according to claim 14, wherein the release film is a blue film.

16. The transfer device according to claim 14, wherein the transfer device or the at least one of the pick-and-place modules further comprises:
at least one pin, located on a second side of the release film relative to the first side.

17. The transfer device according to claim 1, wherein the electronic component comprises a passive component, an active component, or a combination of the passive component and the active component.

18. The transfer device according to claim 1, wherein the electronic component comprises a capacitor, a resistor, an inductor, a diode, a transistor, a sensor, a micro-electromechanical system (MEMS) element, or a chip.

19. The transfer device according to claim 1, wherein the electronic component comprises a modulating element to modulate at least one of a frequency, a phase, and an amplitude of an electromagnetic wave.

20. The transfer device according to claim 1, wherein a size of the substrate is not limited by a radius of the rotating arm.
